(19) United States
(12) Patent Application Publication
(10) Pub. No.: US 2011/0198720 A1
(43) Pub. Date: Aug. 18, 2011

(54) THERMAL-TYPE INFRARED SOLID-STATE IMAGING ELEMENT

(76) Inventor: Shigeru Tohyama, Tokyo (JP)

(21) Appl. No.: 13/123,939

(22) PCT Filed: Oct. 6, 2009
(86) PCT No.: PCT/JP2009/067426

§ 371 Date: Apr. 13, 2011

(30) Foreign Application Priority Data
Oct. 23, 2008 (JP) 2008-273564

(51) Int. Cl. H01L 31/101; H01L 27/14

(52) U.S. Cl. 257/467; 257/E31.054

(57) ABSTRACT

A thermal-type infrared solid-state imaging element is provided with a pixel having a diaphragm (1), a substrate, and a pair of supporting sections which support the diaphragm (1) by being spaced apart from the substrate. The supporting section has a first supporting section (2) on the same level as the diaphragm (1), and a second supporting section (3) on a level between the diaphragm (1) and the substrate. The second supporting section (3) is composed of a beam (4) having one or more bending points (8), a first contact section (5) on one end portion of the beam (4), and a second contact section (6) on the other end portion of the beam (4). The beam (4) and the second contact section (6) of the second supporting section (3) of each pixel exist underneath the diaphragm (1) of another pixel.

### TECHNICAL FIELD

The present invention relates to a thermal-type infrared solid-state imaging element, and more particular to the construction of a supporting section that thermally isolates and supports a diaphragm.

### BACKGROUND ART

Typically, a thermal-type infrared solid-state imaging element absorbs infrared rays that are emitted from a body by an infrared absorption film, and converts the rays to heat, and raises the temperature of a heat-sensitive resistor such as a thin bolometer film of a diaphragm having micro-bridge structure, changing the resistance of the heat-sensitive resistor. The temperature of an object is measured from the change in resistance of this heat-sensitive resistor.

This kind of thermal-type infrared solid-state imaging element includes a light receiving section (diaphragm) that comprises thin bolometer film, and a supporting section that comprises metal wiring that connects the thin bolometer film with a readout circuit that is formed beforehand on a Si substrate. This supporting section supports the light receiving section above the Si substrate via a space. When the incident infrared rays are absorbed by the infrared-ray absorption film and the temperature of the light receiving section rises, the resistance of the thin bolometer film changes, and that change in resistance is detected by the readout circuit and output as an electrical signal.

In order to increase the sensitivity (S/N ratio) of the thermal-type infrared solid-state imaging element described above, it is important first to increase the amount of incident infrared light on the light receiving section. In order to accomplish that, it is necessary to increase the ratio (aperture ratio) of the surface of the light receiving section with respect to the pixel. Second, it is important to suppress the flow of heat that occurs due to the incident infrared rays. In order to accomplish this, it is necessary to reduce the thermal conductance of the supporting section.

As a method for reducing the thermal conductance of the supporting section, there is a method of reducing the cross-sectional area of the supporting section, and a method of increasing the length of the supporting section. However, when the cross-sectional area of the supporting section is reduced, the strength for supporting the light receiving section decreases. Therefore, the method of increasing the length of the supporting section is effective in suppressing heat flow. However, in thermal-type infrared solid-state imaging elements that are currently used, the supporting section is formed between the light receiving sections of adjacent pixels. Therefore, the aperture ratio is decreased by the amount that the length of the supporting section is increased.

To solve this problem, [Patent Literature 1] discloses a thermal-type infrared sensor that is capable of increasing the aperture ratio without changing the thermal capacity. FIG. 6 is a perspective diagram of the construction of the thermal-type infrared sensor disclosed in [Patent Literature 1]. As illustrated in FIG. 6, that thermal-type infrared sensor is constructed such that a supporting unit that comprises a bridge section, a first column section and second column section supports the infrared light receiving section above a semiconductor substrate via a space M. The bridge section, the first column section and second column section are formed underneath the infrared light receiving section such that part or all is covered by the infrared light receiving section.

A technique for achieving high sensitivity even when the size of a pixel is reduced is disclosed in [Patent Literature 2]. FIG. 7A is a perspective diagram of the construction of the thermal-type infrared sensor disclosed in [Patent Literature 2]. FIG. 7B is a top view of the construction of the thermal-type infrared sensor disclosed in [Patent Literature 2]. As illustrated in FIG. 7A and FIG. 7B, [Patent Literature 2] discloses a thermal-type infrared sensor that is constructed such that the light receiving section is supported by supporting legs such that the light receiving section is separated from the substrate, the supporting legs extend outside the range of the pixel, and the supporting legs of adjacent pixels are separated from and extend nearly parallel. [Patent Literature 2], in addition to construction such as illustrated in FIG. 7A and FIG. 7B, discloses construction of supporting legs that are located within the pixel pitch and are bent inside a plane that is parallel with the substrate surface, or construction in which a pair of supporting legs are correspondingly located, and that pair of supporting legs extend from the corresponding light receiving section in opposite directions from each other.

### RELATED ART LITERATURE

### Patent Literature

[Patent Literature 1]: Unexamined Japanese Patent Application KOKAI Publication No. H10-185681
[Patent Literature 2]: Unexamined Japanese Patent Application KOKAI Publication No. 2000-292257

### DISCLOSURE OF INVENTION

### Problems to be Solved by the Invention

In the construction of the thermal-type infrared sensor disclosed in [Patent Literature 1 and 2], in the case of a pixel array, there is a problem in that anomalies or patchiness of sensitivity distribution between pixels, and variation or fluctuation of sensitivity occurs. This is described in detail below.

In the construction disclosed in [Patent Literature 1 and 2], the infrared light receiving section (diaphragm) and supporting section (second column section or supporting legs) are connected over a large area. Even though that connecting section is in the light receiving section, it is not easy for the temperature to rise due to incident infrared rays, so that connecting section functions as a type of heat sink. FIG. 8 is a top view schematically illustrating the temperature distribution in the thermal-type infrared sensor disclosed in [Patent Literature 1 and 2]. As illustrated in FIG. 8; a temperature distribution gradient occurs in the light receiving section (diaphragm). In the case of a pixel array, a thermo-sensitive resistor (temperature detector) is patterned above the light receiving section (diaphragm). However, due to X-Y (parallel movement) positional error and θ (rotational angle) alignment error of the reticule of a mesh exposure apparatus (stepper) that is used during manufacturing, and further due to X-Y positional error and θ (rotational angle) alignment error of a wafer, relative positional misalignment between the light receiving section (diaphragm) and thermo-sensitive resistor (temperature detector) occurs. Various elements are affected in this relative positional misalignment, so must not be the same between pixels. Therefore, when a temperature distribution gradient occurs above the light receiving section (diaphragm) as described above, an abnormal sensitivity distribution or patchiness between pixels occurs due to this relative positional misalignment. The relative positional misalignment is such that it is larger around the chip perimeter than in the chip center, and is larger around the perimeter of a wafer than in the center of a wafer. Therefore, there is a problem in that chips on the outer circumference of a wafer, for example, may not satisfy the performance to become a product, causing a decrease in yield.

Recently the need for the use of this kind of uncooled sensor in vehicles such as automobiles for improving safety is increasing. For such usage, making such sensors more compact and less expensive is desired. By making a pixel smaller, the pixel dimension in the planar direction is reduced; however, the dimension in the height direction is not reduced, so that as a result the aspect ratio of the pixel (dimension in the height direction/dimension of the light receiving section in the planar direction) becomes large. As the aspect ratio of the pixel becomes large, it becomes easy for the light receiving section to tilt due to acceleration in the planar direction that occurs due to vibration and the like when installed in a vehicle. The light receiving surface tilts in the direction of incident light, so that it becomes easy for variation or fluctuation in image sensitivity to occur. Particularly, in the construction disclosed in [Patent Literature 1 and 2], the aspect ratio of the pixel is large, so that the spacing between the contact sections that connect the supporting section and substrate becomes narrow. Or, because the supporting legs extend in a set direction in a linear or stepped shape, the resistance force against the tilt of the light receiving section described above becomes even less, and the problem of variation or fluctuation of the image sensitivity becomes more severe.

Taking the situation above into consideration, the object of the present invention is to provide thermal-type infrared solid-state imaging element in which a diaphragm is supported by a supporting section, and is capable of suppressing abnormal sensitivity distribution or patchiness between pixels, and variation or fluctuation in image sensitivity caused by the construction of the supporting section.

### Means for Solving the Problems

In order to solve the problems above, the thermal-type infrared solid-state imaging element of the present invention comprises: a plurality of pixels having at least: a substrate on which an integrated circuit is formed for reading signals, and that comprises that integrated circuit and a connecting electrode; a diaphragm having an infrared absorption section that is heated by absorbing infrared rays, a temperature detection section whose temperature changes by the heat from the infrared absorption section and detects changes in the temperature of the infrared absorption section, and an electrode section that is electrically connected to the temperature detection section; this diaphragm being located in a space provided on the surface of one side of the substrate; and a pair of supporting sections that support the diaphragm such that the diaphragm is separated from the surface on one side of the substrate, and of which at least part is formed of an electrically conductive material, so as to form wiring that electrically connects the electrode section of the diaphragm with the connecting electrode of the substrate; wherein the pair of supporting sections each has a first supporting section that is provided on the same level as the diaphragm, part thereof connecting to the diagram by a connecting section, and a second supporting sections that is provided on a level between the diaphragm and the substrate; the second supporting section has a beam that has one or more bending points, a first contact section that is provided on one end of the beam, and a second contact section that is provided on the other end of the beam; the beam and second contact section of each of the pair of supporting sections are located on both sides on the outside of the diaphragm with the diaphragm in between; each of the pair of supporting sections forms a mechanical and electrical connection between the first supporting section and the first contact section of the second supporting section, and forms a mechanical and electrical connection between the second contact section of the second supporting section and the connecting electrode; and the beam and second contact section of the second supporting section of each pixel are located underneath the diaphragm of another pixel.

### Advantage of the Invention

With the thermal-type infrared solid-state imaging element of the present invention, the supporting section of the thermal-type infrared solid-state imaging element supports the diaphragm making it possible to suppress abnormal or patchy sensitivity distribution between pixels and variation or fluctuation in the pixel sensitivity due to the construction of the supporting section.

### BRIEF DESCRIPTION OF DRAWINGS

FIG. 1 is a top view illustrating the pixel construction of a thermal-type infrared solid-state imaging element of an embodiment of the present invention.

FIG. 2A is a cross-sectional diagram illustrating the construction of a thermal-type infrared solid-state imaging element of an embodiment of the invention, and focuses on one pixel.

FIG. 2B is a cross-sectional diagram illustrating the construction of a thermal-type infrared solid-state imaging element of an embodiment of the invention, and illustrates the positional relationship with adjacent pixels.

FIG. 3 is a top view illustrating other Pixel construction of a thermal-type infrared solid-state imaging element of an embodiment of the invention.

FIG. 4 is a top view illustrating the other construction of a supporting section of a thermal-type infrared solid-state imaging element of an embodiment of the invention.

FIG. 5A is a cross-sectional diagram illustrating the manufacturing process for forming a first sacrificial level in a thermal-type infrared solid-state imaging element of an embodiment of the invention.

FIG. 5B is a cross-sectional diagram illustrating the manufacturing process for forming a first insulating film.

FIG. 5C is a cross-sectional diagram illustrating the manufacturing process for opening a contact in the first insulating film.

FIG. 5D is a cross-section diagram illustrating the manufacturing process for forming a thin metal film for forming first wiring.

FIG. 5E is a cross-sectional diagram illustrating the manufacturing process for performing patterning of the first wiring.

FIG. 5F is a cross-sectional diagram illustrating the manufacturing process for forming a thin metal film for forming second wiring.

FIG. 5G is a cross-sectional diagram illustrating the manufacturing process for performing patterning of the second wiring.

FIG. 5H is a cross-sectional diagram illustrating the manufacturing process for forming a second insulating film.

FIG. 5I is a cross-sectional diagram illustrating the manufacturing process for performing patterning of the first insulating film and second insulating film.

FIG. 5J is a cross-sectional diagram illustrating the manufacturing process for forming a second sacrificial layer.

FIG. 5K is a cross-sectional diagram illustrating the manufacturing process for forming a third insulating film.

FIG. 5L is a cross-sectional diagram illustrating the manufacturing process for forming and performing patterning of a thin bolometer film.

FIG. 5M is a cross-sectional diagram illustrating the manufacturing process for forming a fourth insulating film.

FIG. 5N is across-sectional diagram illustrating the manufacturing process for opening a contact in the fourth insulating film.

FIG. 5O is a cross-sectional diagram illustrating the manufacturing process for forming a thin metal film for forming third wiring.

FIG. 5P is a cross-sectional diagram illustrating the manufacturing process for performing pattering of the third wiring.

FIG. 5Q is a cross-sectional diagram illustrating the manufacturing process for forming a fifth insulating film.

FIG. 5R is a cross-sectional diagram illustrating the manufacturing process for performing patterning of the fifth insulating film, fourth insulating film and third insulating film.

FIG. 5S is a cross-sectional diagram illustrating the manufacturing process for removing the first sacrificial layer and second sacrificial layer.

FIG. 6 is a perspective diagram illustrating the construction of a thermal-type infrared sensor disclosed in [Patent Literature 1].

FIG. 7A is a perspective diagram illustrating the construction of a thermal-type infrared sensor disclosed in [Patent Literature 2].

FIG. 7B is a top view illustrating the construction of a thermal-type infrared sensor disclosed in [Patent Literature 2].

FIG. 8 is a top view that schematically illustrates the temperature distribution in the thermal-type infrared sensor disclosed in [Patent Literature 1] and [Patent Literature 2].

FIG. 9 is a top view illustrating the effect of improving the temperature distribution of the pixel in a thermal-type infrared solid-state imaging element of the present invention.

### BEST MODE FOR CARRYING OUT THE INVENTION

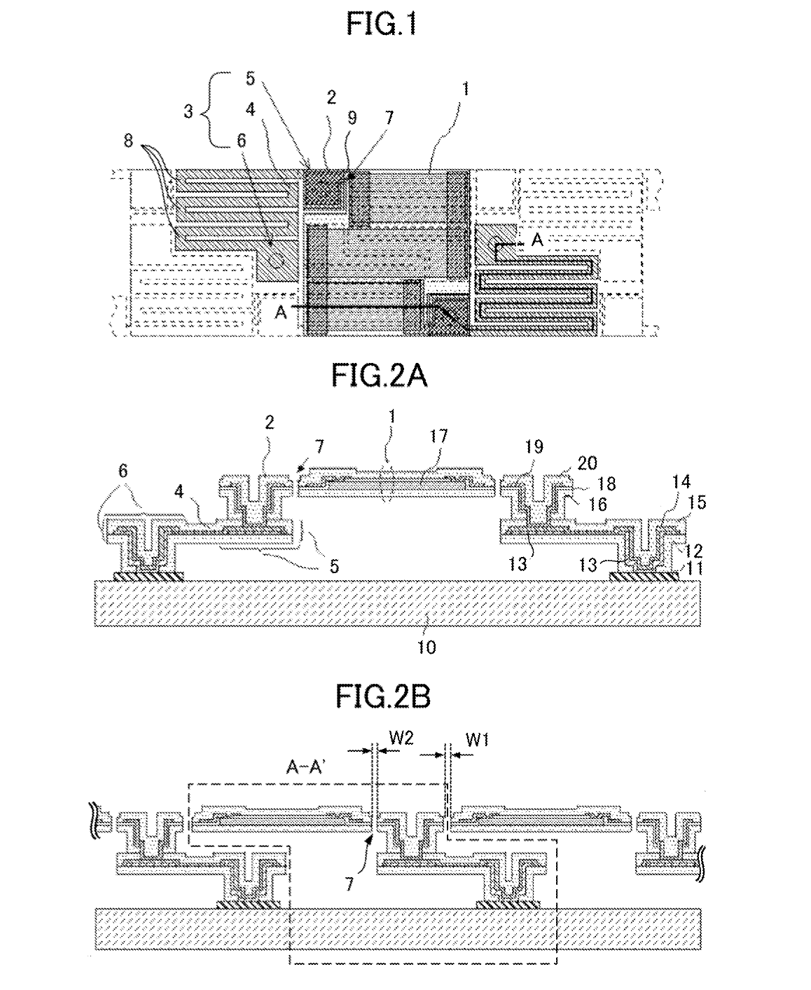

An embodiment of the thermal-type infrared solid-state imaging element of the present invention is explained in detail using FIG. 1 to FIG. 5S. FIG. 1 is a top view illustrating the construction of the thermal-type infrared solid-state imaging element of this embodiment. In FIG. 1, the pixel being focused on is illustrated by solid lines and hatching. The pixels adjacent to the pixel being focused on are illustrated using dashed lines. FIG. 2A is a cross-sectional diagram illustrating the construction of the thermal-type infrared solid-state imaging element of this embodiment, and is a diagram of one pixel being focused on. In other words, FIG. 2A illustrates the construction of the path of one pixel from one supporting section to the other supporting section via the diaphragm. However, the separation by the thin bolometer film and the metal wiring (part of third wiring 19) connecting between thin bolometer films are omitted. To simplify the creation of the drawing, the scale of the path in beam 4 and the diaphragm 1 differs from the scale in FIG. 1.

FIG. 2B is a cross-sectional diagram illustrating the construction of the thermal-type infrared solid-state imaging element of this embodiment, and illustrates the positional relationship with the adjacent pixels. The area enclosed in dashed lines illustrates a cross section that is cut through section line A-A′ of the pixel focused on in FIG. 1. However, as in FIG. 2A, to simplify creation of the drawing, the scale of the path in beam 4 and the diaphragm 1 differs from the scale in FIG. 1. A cross section that similarly cuts through the section line A-A′ is illustrated for both the adjacent pixel on the left and right of the one pixel being focused on. In other words, FIG. 2B illustrates construction in which a plurality of pixels that includes the one pixel being focused on are arranged at a pitch in the horizontal direction of the diaphragm length, plus, width W1 between diaphragms. As illustrated in FIG. 2B, with the thermal-type infrared solid-state imaging element of this embodiment, the width W1 between diaphragms can be a width that is about the same as the width W2 of a slit 7 (in other words, a length about the same as the connecting section 9). This is because the beam 4 and a second contact section 6 are located underneath the diaphragm of adjacent pixels.

As illustrated in FIG. 1, FIG. 2A and FIG. 2B, the thermal-type infrared solid-state imaging element of this embodiment comprises: a diaphragm 1 that absorbs incident infrared rays, a Si substrate 10 with readout circuit (the readout circuit is not illustrated in the figures) on which an integrated circuit is formed for reading signals, and a pair of supporting sections that support the diaphragm 1 such that it is separated from the Si substrate 10 with readout circuit.

The diaphragm 1 includes a thin bolometer film 17, a fifth insulating film 20, a third insulating film 16, a fourth insulating film 18, and part of third wiring 19. The thin bolometer film 17 is a temperature change detection mechanism, and is separated into three sections. The third insulating film 16 is formed on the bottom layer side of the thin bolometer film 17, and the fifth insulating film 20 and fourth insulating film 18 are formed on the upper layer side such that they cover the thin bolometer film 17. This thin bolometer film 17 is made of a vanadium oxide (V₂O₃, VO_{X}) film or titanium oxide (TiO_{X}) film having a film thickness of 30 to 200 nm. The divisions of the divided thin bolometer film 17 are connected in series by the third wiring 19. The number of divisions of the thin bolometer film 17 should be selected such that the series resistance of the entire bolometer is a desired value. The three insulating films that cover the thin bolometer film 17 will be explained in detail later; however, are Si oxide (SiO, SiO₂) films, for example, that function as an infrared ray absorption section.

The third wiring 19 is covered by the third insulating film 16 and fourth insulating film 18 on the bottom layer side, and by the fifth insulating film 20 on the top layer side. The third wiring 19 runs from the end section of thin bolometer film 17, to which it is connected in series, through the connecting section 9, to a first contact section 5, forming a first supporting section 2. As illustrated in FIG. 1, part of the connecting section 9 connects the diaphragm 1 and first supporting section 2, and is an area that is reduced by the slit 7 to a width less than that of the first supporting section 2. Here, the reason for the slit 7 is to reduce the size of the connecting section 9, which is the connecting portion between the diaphragm 1 and first supporting section 2, and to keep heat from flowing out from the diaphragm 1. The connecting section 9 should have length, width and thickness capable of mechanically supporting the diaphragm 1 such that it is separated from the Si substrate 10 with readout circuit. For example, the connecting section 9 has width and thickness that is about the same as the beam 4 of the second supporting section 3. In the first contact section 5, first wiring 13 and second wiring 14 is formed on the first insulating film 12. The third wiring 19 is connected to the second wiring 14 by a contact hole that is formed in the second insulating film 15, third insulating film 16 and fourth insulating film 18. The second wiring 14 runs from through the beam 4 in which a plurality of bending points 8 are formed up to a connecting electrode 11 that is formed on the Si substrate 10 with readout circuit. In a preferred form of the invention, the beam 4 of the embodiment illustrated in FIG. 1 has construction such that it changes direction at the bending points 8. Finally, the second wiring 14 connects to the connecting electrode 11 via the first wiring 13 that is formed in a contact hole that is formed in the first insulating layer 12.

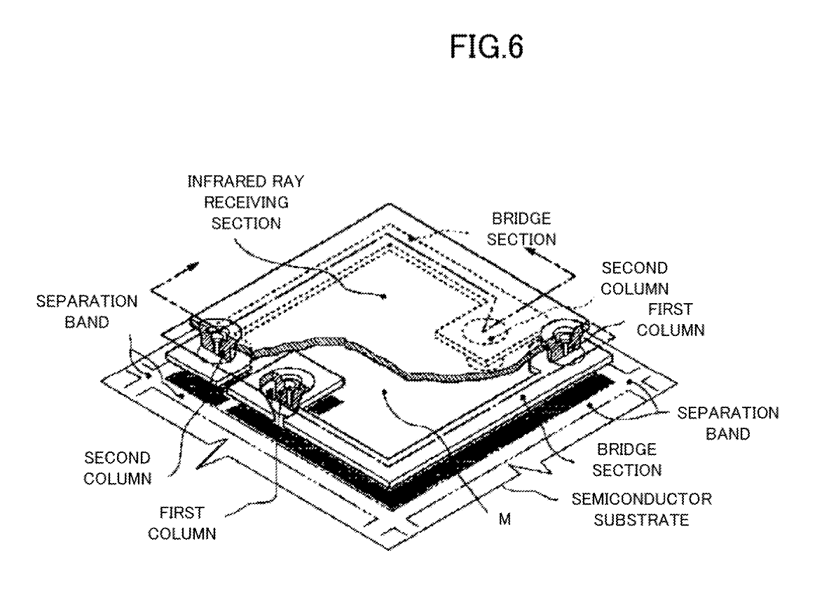

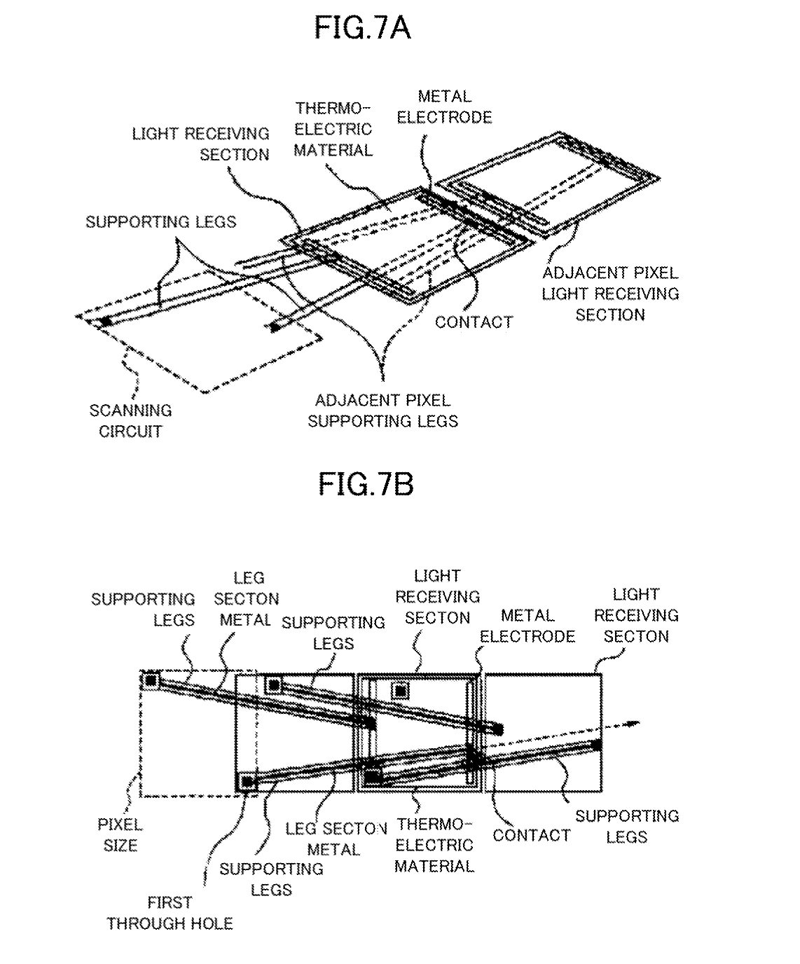

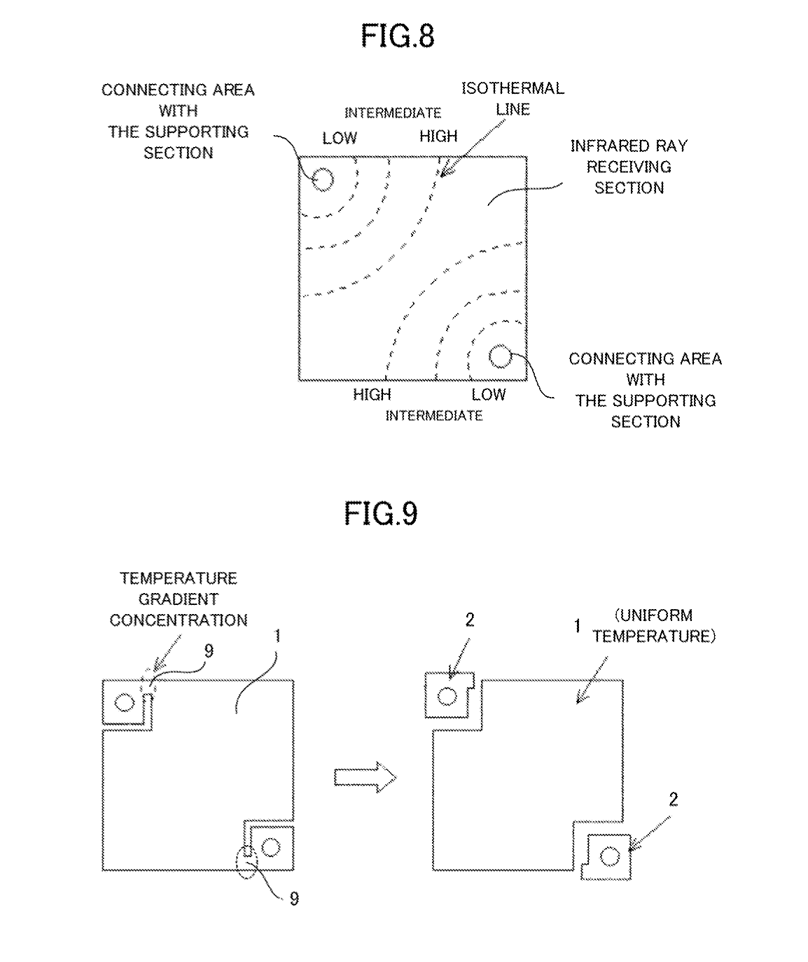

Here, in the thermal-type infrared solid-state imaging element (thermal-type infrared sensor) that is disclosed in [Patent Literature 1] and illustrated in FIG. 6, the connecting sections between each of the supporting sections and the substrate (second contact section 6 in FIG. 1) are both located under the light receiving section (diaphragm 1 in FIG. 1). Therefore, it is not possible to increase the spacing between connecting sections between the supporting sections and the substrate. In other words, it is not possible to make the space between the connecting sections more than the size of the light receiving section (diaphragm 1). As a result, there was a problem in that it is not possible to stably support the light receiving unit by two supporting sections.

Even in the case of the thermal-type infrared solid-state imaging element disclosed in [Patent Literature 2] and illustrated in FIG. 24, the two supporting sections are brought out in the same direction in a linear shape, so similar to as above, it is not possible to increase the space between connecting sections. As a result, there was a problem, in that the strength of the supporting sections cannot be increased, and the two supporting sections cannot stably support the light receiving section.

Therefore, as a first feature of the thermal-type infrared imaging element of this embodiment, the pair of supporting sections that support the diaphragm 1 is constructed such that a first supporting section 2 is formed on the same layer as the diaphragm 1, and a second supporting section is formed on the layer between the diaphragm 1 and Si substrate 10 with readout circuit. As a second feature, two second supporting sections 3 are brought out to the outside on both sides with the diaphragm 1 in the middle (preferably point symmetrical with the diaphragm 1 in the center). As a third feature, the beams 4 of each of the second supporting sections 3 are formed such that the path length is long, according to have one or more bending points 8 under the diaphragm 1 of adjacent pixels (preferably according to be constructed such that the direction turns back at the bending points). As a fourth feature, the diaphragm 1 and first supporting section 2 are connected in part by the connecting section 9 (preferably, are connected in part by the connecting section 9, which is an area that is made more narrow than the width of the first supporting section 2 by the slit 7).

As a result of the first feature of the thermal-type infrared imaging element of this embodiment, the main mechanical an electrical connection between the diaphragm 1 and Si substrate 10 with readout circuit is formed between the first supporting section 2 having large surface area and the first contact section 5 of the second supporting section 3. Therefore, as mentioned as the fourth feature, the diaphragm 1 and first supporting section 2 can be connected by the connecting section 9 (very small part of a short beam). FIG. 9 is a top view illustrating the effect of improving the temperature distribution of the pixel in the thermal-type infrared solid-state imaging element of the present invention. As illustrated by the left figure in FIG. 9, the temperature gradient that occurs on the diaphragm 1 as described above, can be concentrated around this connecting section 9. Therefore, as illustrated in the right figure of FIG. 9, it is possible to make the temperature uniform inside the diaphragm 1. The temperature inside the diaphragm 1 is uniform, so even though relative positional misalignment may occur in the diaphragm 1 and thermo-sensitive resistor (temperature detector) pattern, anomalies or patchiness of sensitivity distribution does not occur between pixels, thus it is possible to improve yield.

As a result of the second and third features, together with an increase in the mechanical strength of the supporting sections, it is possible to give the supporting sections a function such as a spring for resistance to impact and resistance to vibration. Particularly as a result of the second feature, when compared with construction that brings out the supporting sections underneath the diaphragm 1 as described above, it is possible to increase the space between the contact sections of the second supporting section 3 and substrate, so that it is possible to stably support the diaphragm 1. As a result, it becomes difficult for the light receiving section to tilt due to acceleration that acts in the in-plane direction, and it is possible to maintain the light receiving surface fixed with respect to the incident direction. Consequently, it is possible to suppress variation or fluctuation in the sensitivity of the thermal-type infrared imaging element. Furthermore, as a result of the second feature, the path length of the second supporting section can be lengthened, and the sensitivity can be improved.

The construction of the thermal-type infrared imaging element of this embodiment illustrated in FIG. 1 and FIG. 2 is only an example, and as long as the construction comprises the four features above, the shape and construction of the first supporting section 2 and second supporting section 3 are arbitrary. For example, in FIG. 1, the second contact section 6 is located at a position near the diaphragm 1; however, the second contact section 6 could be located at a position separated from the diaphragm 1. By increasing the space between each of the second contact sections 6 of the pair of supporting sections, it is possible to more stably support the diaphragm 1. Moreover, in FIG. 1, the second supporting section 3 has construction such that it turns back and forth five times at the bending points 8; however, the number and location of bending points, and further, whether or not to use turn around construction at the bending points 8 is arbitrary. Furthermore, in FIG. 1, the width of the beam 4 of the second supporting section 3 is fixed; however, the width could gradually become narrower (or wider) going from the diaphragm 1 side toward the second contact section 6 side, or the width could in places be narrow (or wide).

The width, length, thickness or shape of the connecting section 9 and slit 7 are not limited to the construction illustrated in the figures. For example, in FIG. 1, the slit 7 is formed by cutting an L shape in each first supporting section 2 from one location (horizontal edge in the figure); however, can also be formed by cutting from two locations (horizontal edge and vertical edge in the figure). When the width of the slit 7 is wide, the aperture ratio becomes small, and when the cut amount is short, the heat flow out to the first supporting section 2 becomes large. Therefore, it is preferred that the width of the slit 7 be made as narrow as possible, and that the cut amount be as long as possible and still be able to maintain mechanical strength. In other words, it is preferred that the slit 7 be formed such that the length of the connecting section 9 is as long as possible, and the width of the connecting section 9 is as narrow as possible and still be able to maintain mechanical strength.

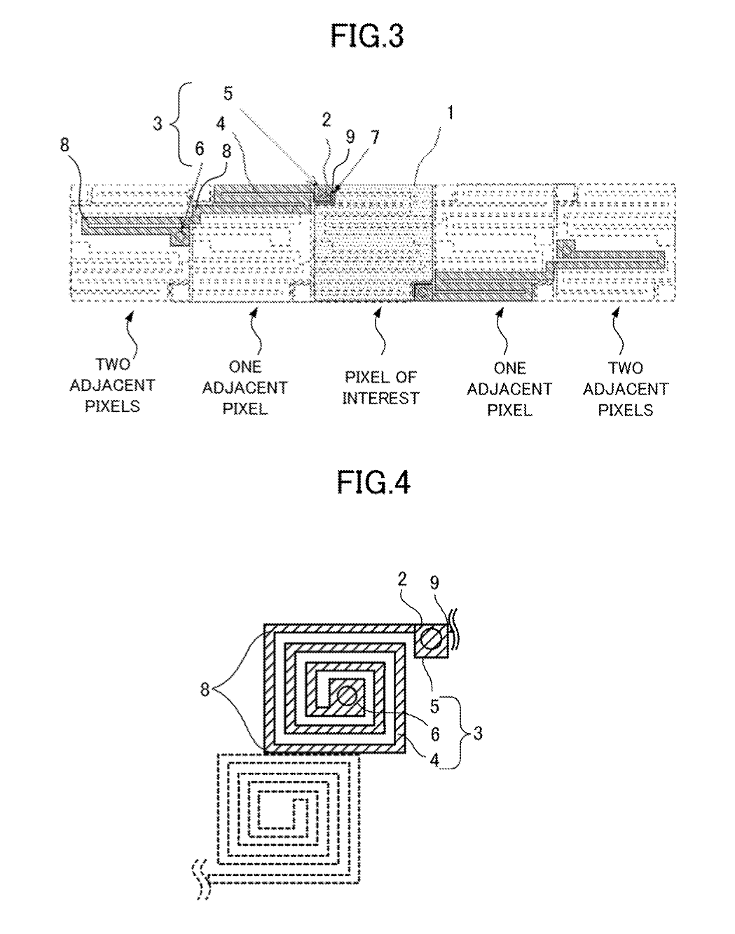

In FIG. 1 and FIG. 2, the second supporting section 3 is brought out only underneath the diaphragm 1 of the adjacent pixel; however, for example, each second supporting section 3 can be brought out to underneath the diaphragm 1 of two or more adjacent pixels (two in the figure). FIG. 3 is a top view illustrating other construction of a thermal-type infrared solid-state imaging element of this embodiment. As illustrated in FIG. 3, the second contact section 6 can be located underneath the diaphragm 1 of two adjacent pixels. Or the second contact section 6 can be located underneath the diaphragm 1 of one adjacent pixel, and after the second supporting section 3 is brought out underneath the diaphragm 1 of two adjacent pixels, can be returned to underneath the diaphragm 1 of one adjacent pixel and connected to the Si substrate 10 with readout circuit.

In FIG. 1 and FIG. 2, the case of construction in which the beam 4 turns back at all of the plurality of bending points 8 was described, and in FIG. 3, the case of construction in which the beam 4 turns back at only some of the plurality of bending points 8 was described. However, in the thermal-type infrared solid-state imaging element of the present invention it is possible for the beam 4 to have one or more bending points 8. FIG. 4 is a top view illustrating other construction of a supporting section of the thermal-type infrared solid-state imaging element of this embodiment. The supporting section of the pixel being focused on is illustrated by solid lines and hatching. The supporting section of an adjacent pixel to the pixel being focused on is illustrated by dashed lines. A supporting section as illustrated in FIG. 4 in which none of the bending points 8 of the beam 4 have turn back construction is also included within the range of the present invention.

In FIG. 1 to FIG. 3, the supporting section comprises a first supporting section 2 that is on the same level as the diaphragm 1, and a second supporting section 3 that is on a layer between the diaphragm 1 and Si substrate 10 with readout circuit. However, another supporting section can be provided on an nth (integer n≧1) layer between the second supporting section 3 and the Si substrate 10 with readout circuit. That other supporting section has at least a first contact section and second contact section as in the second supporting section 3. Connection can be performed in order such that the second contact section 6 of the second supporting section 3 is connected to the first contact section of another supporting section one layer below, and the second contact of that other supporting section is connected to the first contact section of another supporting section one layer below and so on. In this case, construction can be such that the second contact section of the supporting section of the very bottom layer is mechanically and electrically connected with the connecting electrode 11.

Moreover, a feature of the thermal-type infrared solid-state imaging element of this embodiment is in the construction of the supporting section, with the materials and film thickness of the first supporting section 2 and second supporting section 3 being arbitrary. For example, the first insulating layer 12, second insulating layer 15, third insulating layer 16, fourth insulating layer 18 and fifth insulating layer 20 can be made using a Si oxide film (SiO, SiO₂), Si nitride film (SiN, Si₃N₄), or Si nitride-oxide film (SiON). Also, the first wiring 13, second wiring 14 and third wiring 19 can be made of aluminum (Al), copper (Cu), gold (Au), titanium (Ti), tungsten (W), molybdenum (Mo), or an alloy such as titanium aluminum vanadium (TiAlV), or can be made of a semiconductor such as Si with a high density of impurities.

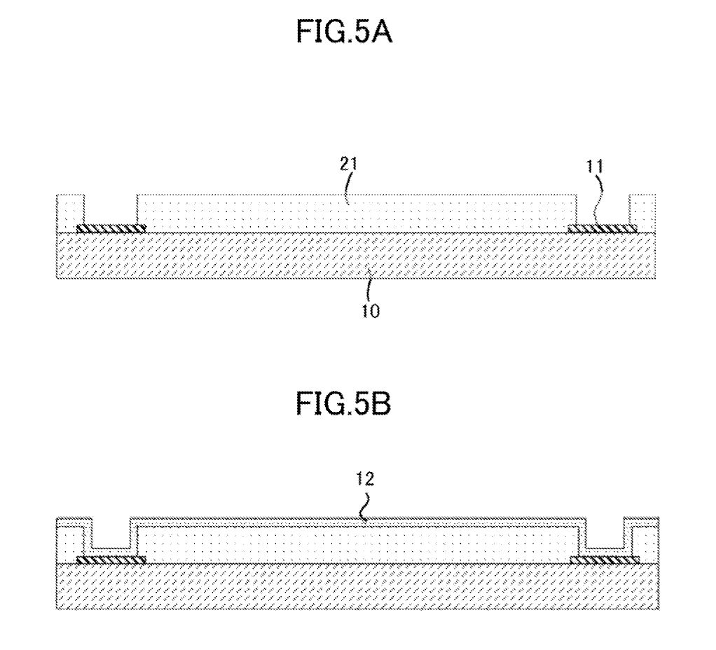

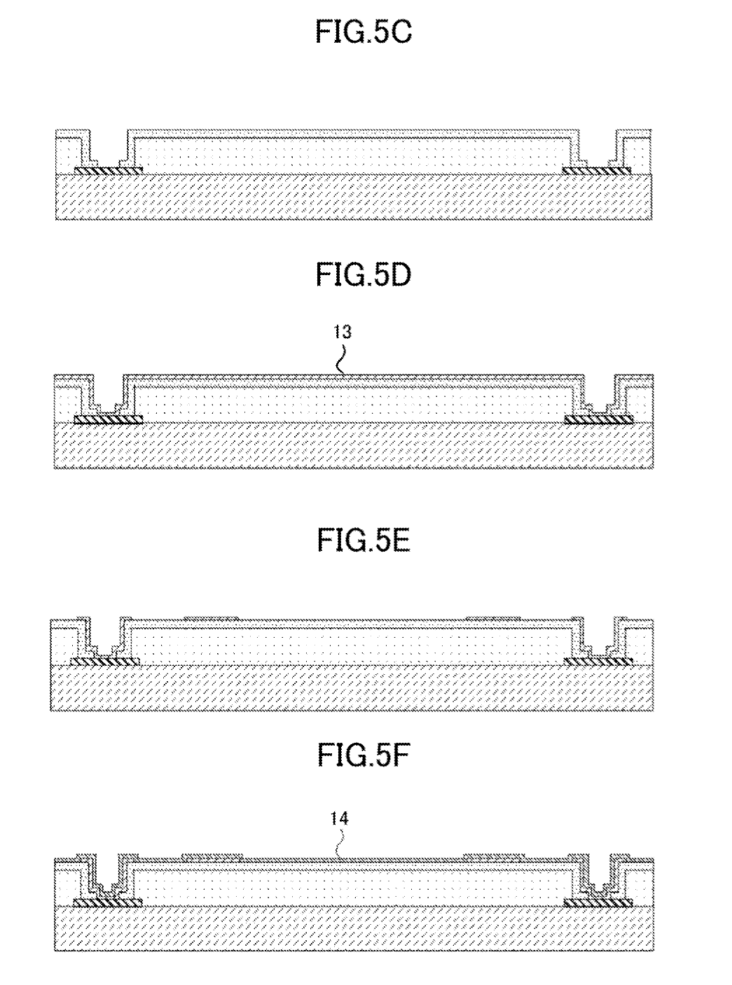

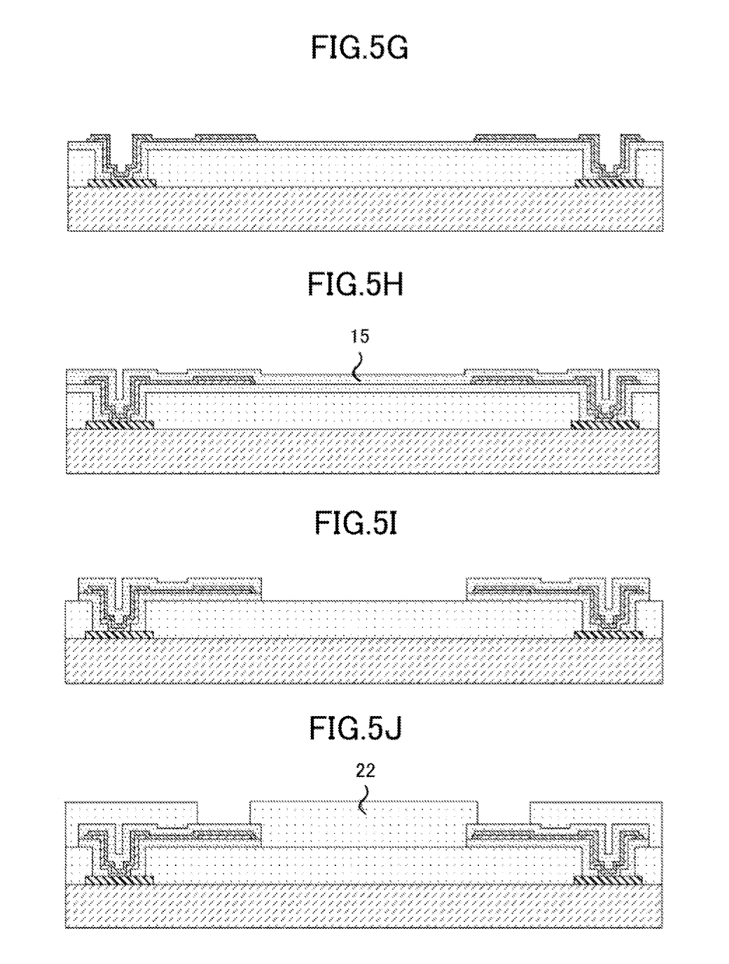

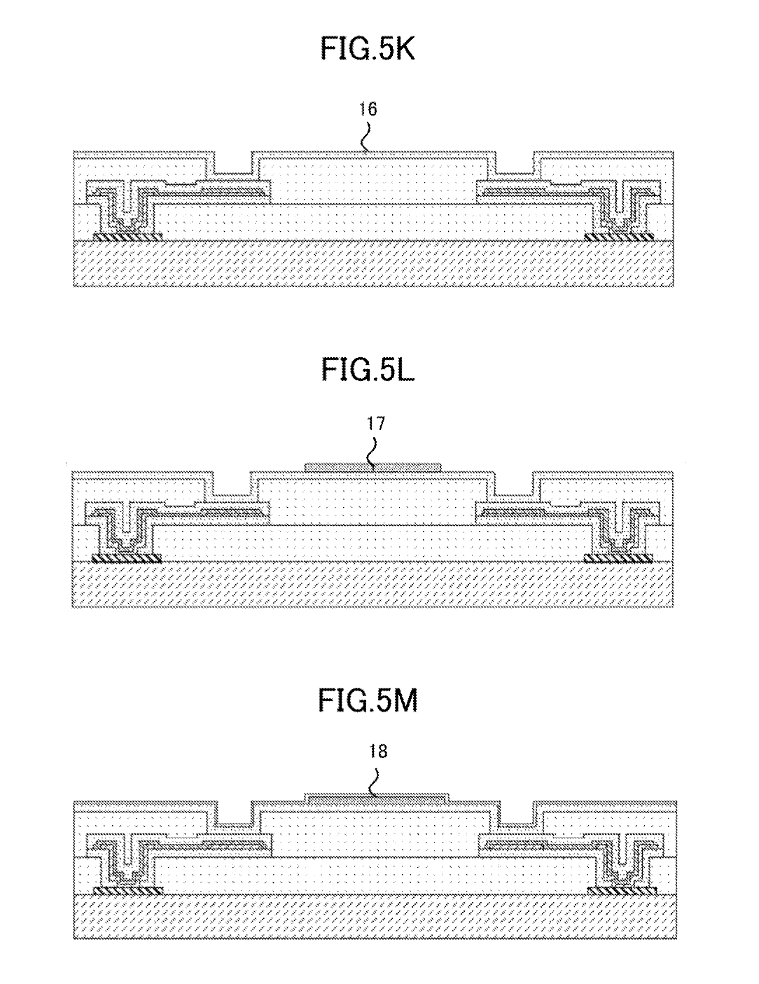

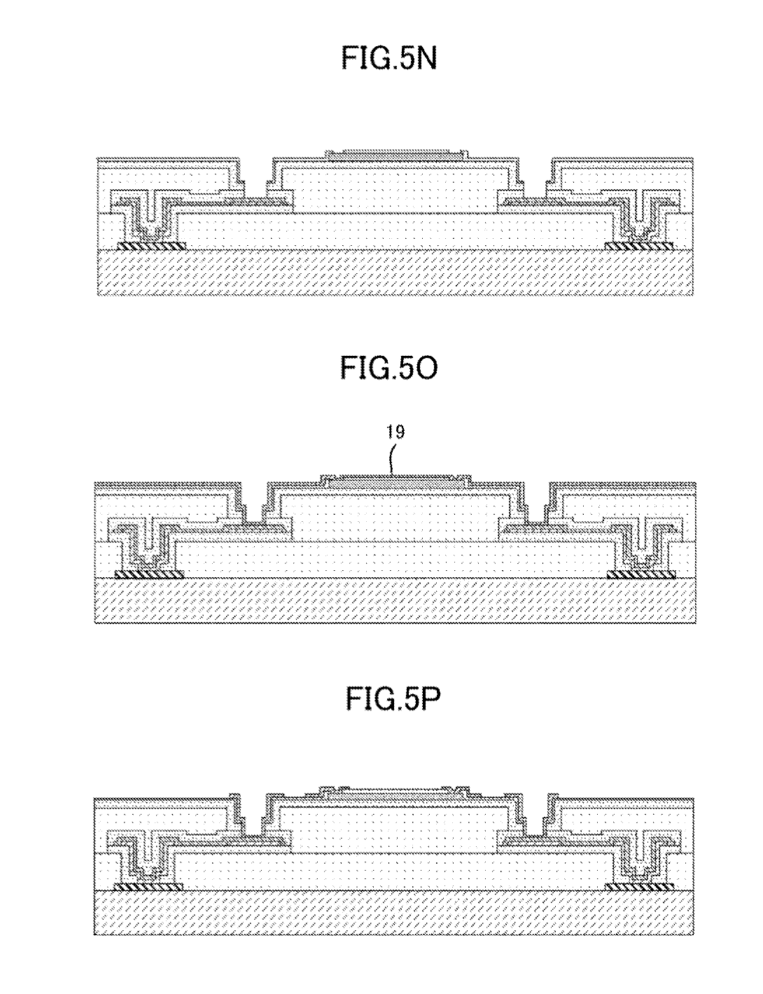

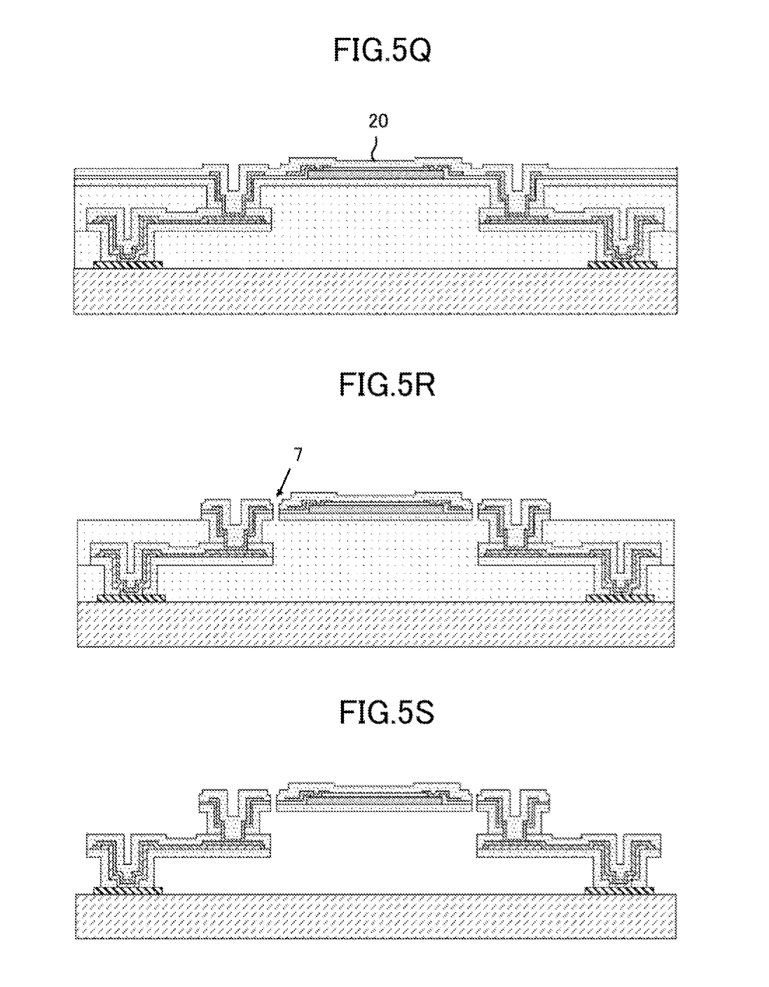

The method of manufacturing the thermal-type infrared solid-state imaging element of this embodiment is explained in detail below. FIGS. 5A to 5S are cross-sectional diagrams illustrating the main manufacturing process for the thermal-type infrared solid-state imaging element of this embodiment.

First, a plurality of signal readout circuits (not illustrated in the figure), a plurality of metal reflection films (not illustrated in the figure) and a plurality of connecting electrodes 11 which are terminal electrodes of the signal readout circuits, are formed on a Si substrate 10 by a normal Si integrated circuit manufacturing process. It is not illustrated in FIGS. 5A to 5S; however, an insulating protective film can be formed so as to cover the entire Si substrate 10 with readout circuit, metal reflective film or connecting electrodes 11.

Next, as illustrated in FIG. 5A, a first sacrificial layer 21 for forming a space between the second supporting sections 3 and Si substrate 10 with readout circuit is formed on the Si substrate 10 with readout circuit except in the portions where the second contacts 6 that connect the supporting sections 3 and connecting electrodes 11 will be formed. This first sacrificial layer 21 is formed, for example, by applying a photosensitive polyimide coating, performing patterning by exposure and development, and then performing heat treatment. The thickness of the first sacrificial layer 21 is, for example, 0.5 to 3 μm.

Next, as illustrated in FIG. 5B, a first insulating film 12 is formed by the plasma CVD method such that it covers the first sacrificial layer 21. This first insulating layer 12 is made of Si oxide film (SiO, SiO₂), Si nitride film (SiN, Si₃N₄) or Si nitride oxide film (SiON) having a film thickness of 50 to 200 nm.

Next, as illustrated in FIG. 5C, using a photoresist pattern that is formed using a known photolithography method as a mask, contact holes for connecting the connecting electrodes 11 and first wiring 13 are opened up in the first insulating layer 12 above the connecting electrodes 11.

Next, as illustrated in FIG. 5D, a thin metal film that will form the first wiring 13 is formed using a sputtering method. This first wiring 13 is made of a metal such as aluminum, copper, gold, titanium, tungsten, molybdenum, or titanium aluminum vanadium alloy having a film thickness of 50 to 200 nm. This first wiring 13 (metal film backing) is provided in order to solve the problems of penetration when forming contact holes for the first contact sections 5, or disconnection in the stepped section of the second contact sections 6. When the thickness of the thin metal film of the second wiring 14 is such that penetration or disconnection in the stepped section is not a concern, the first wiring 13 does not need to be formed. In other words, in this case, it is possible to just form the second wiring 14 that will be located on the beams 4 in the bottom section of the first contact sections 5 and second contact sections 6.

Next, as illustrated in FIG. 5E, using a photoresist pattern that is formed using a known photolithography method as a mask, patterning of the first wiring 13 is performed so that the thin metal film remains in the portions that correspond to the contact holes of the second contact sections 6, and first contact sections 5.

Next, as illustrated in FIG. 5F, a thin metal film that forms second wiring 14 is formed using a sputtering method. This second wiring 14, is made of a metal such as aluminum, copper, gold, titanium, tungsten, molybdenum, or titanium aluminum vanadium alloy having a film thickness of 10 to 200 nm. This second wiring 14 becomes the signal transmission paths in the second supporting sections 3.

Next, as illustrated in FIG. 5G, using a photoresist pattern that is formed using a known photolithography method as a mask, patterning of the second wiring 14 is performed so that the second wiring 14 remains on the path from the first contact sections 5 to the second contact sections 6. First wiring 13 is formed inside the contact holes of the second contact sections 6, so it is possible to prevent steps from being cut in the second wiring 14.

Next, as illustrated in FIG. 5H, a second insulating layer 15 is formed by, for example, the plasma CVD method so that it covers the second wiring 14. This second insulating film 15 is also made of Si oxide film (SiO, SiO₂), Si nitride film (SiN, Si₃N₄) or Si nitride oxide film (SiON) having a film thickness of 50 to 200 nm.

Next, as illustrated in FIG. 5I, using a photoresist pattern that is formed using a known photolithography method as a mask, the first insulating film 12 and second insulating film 15 underneath the diaphragm 1 is removed in, order to form the second supporting sections 3. Partially exposing the polyimide of the first sacrificial layer 21 at the same time is also effective in patterning of the second supporting sections 3.

Next, as illustrated in FIG. 5J, a second sacrificial layer 22 for forming a space between the diaphragm 1 and the second supporting section 3 with readout circuit is formed except in the portions of the first contact sections 5. This second sacrificial layer 22 is formed, for example, by applying a photosensitive polyimide coating, and performing patterning by exposure and development, then performing heat treatment. The thickness of the second sacrificial layer 22 is 0.5 to 3 μm. The first sacrificial layer 21 and second sacrificial layer 22 can be formed using the same material, or can be formed using different materials.

Next, as illustrated in FIG. 5K, a third insulating film 16 is formed using the plasma CVD method so that it covers the first contact sections 5 and second sacrificial layer 22. This third insulating film 16 is made of Si oxide film (SiO, SiO₂), Si nitride film (SiN, Si₃N₄) or Si nitride oxide film (SiON) having a film thickness of 50 to 200 nm.

Next, as illustrated in FIG. 5L, a material film that will form the thin bolometer film 17 is formed using a sputtering method, and patterning of the thin bolometer film is performed so that the material film remains at a position corresponding to the diaphragm 1. This thin bolometer film 17 is made of vanadium oxide (V₂O₃, VOₓ), or titanium oxide (TiOₓ) having a film thickness of 50 to 200 nm.

Next, as illustrated in FIG. 5M, a fourth insulating film 18 is formed using the plasma CVD method so that it covers the thin bolometer film 17. This fourth insulating film 18 is made of Si oxide film (SiO, SiO₂), Si nitride film (SiN, Si₃N₄) or Si nitride oxide film (SiON) having a film thickness of 50 to 200 nm.

Next, as illustrated in FIG. 5N, using a photoresist pattern that is formed using a known photolithography method as a mask, contact holes are opened in the fourth insulating film 18 in order to form contacts between the thin bolometer film 17 and the third wiring 19 formed on that top layer, and contacts between the second wiring 14 of the first contact sections 5 and the third wiring 19 that is formed on that top layer. The first wiring 13 is formed in the first contact sections 5, so that it is possible to prevent penetration when forming the contact holes. The process of opening up contact holes in the thin bolometer film 17 and the process of opening up contact holes in the first contact sections 5 can be divided into separate processes.

Next, as illustrated in FIG. 5O, a thin metal film that will form third wiring 19 is formed by a sputtering method. This third wiring 19 is made of a metal such as aluminum, copper, gold, titanium, tungsten, molybdenum, or titanium aluminum vanadium alloy having a film thickness of 10 to 200 nm. When there is a possibility that disconnection will occur in the contact holes of the first contact sections 5 because the thin metal film forming the third wiring 19 is thin, it is possible to form a metal backing pattern in the same way as for the first wiring 13 before forming the thin metal film that will form the third wiring 19.

Next, as illustrated in FIG. 5P, using a photoresist pattern that is formed using a known photolithography method as a mask, patterning of the third wiring 19 is performed so that the third wiring 19 remains in the path from the end section of the thin bolometer film 17 to the first support sections 2. By doing so, the thin bolometer film 17 is connected to the connecting electrodes 11 via the third wiring 19, second wiring 14 and first wiring 13. FIG. 5P is a cross section of the path that horizontally traverses the slit 7 in FIG. 1, so that the third wiring 19 is broken up on the outside of the thin bolometer film 17, however, the third wiring 19 is continuously formed from the thin bolometer film 17 to the first contact sections 5, avoiding the slit 7.

Next, as illustrated in FIG. 5Q, a fifth insulating film 20 is formed by the plasma CVD method further covering these. This fifth insulating film 20 is made of Si oxide film (SiO, SiO₂), Si nitride film (SiN, Si₃N₄) or Si nitride oxide film (SiON) having a film thickness of 50 to 500 nm.

Next, as illustrated in FIG. 5R, the fifth insulating film 20, fourth insulating film 18 and third insulating film 16 are patterned together in the shape of the diaphragm 1 and first supporting sections 2. When doing this, slits 7 are also formed between the diaphragm 1 and first supporting sections 2. Partially exposing the polyimide of the second sacrificial layer 22 at the same time is also effective in patterning of the diaphragm 1 and first supporting sections 2.

Next, as illustrated in FIG. 5S, by removing the first sacrificial layer 21 and second sacrificial layer 22 by ashing using O₂ gas plasma, the thermal-type infrared solid-state imaging element of this embodiment is completed.

The manufacturing method (process) described above is an example, and as long as the thermal-type infrared solid-state imaging element of this embodiment can be manufactured, the material used and the formation and removal methods and order of processing can be suitably changed to a method known by one skilled in the art. For example, in the method above, the first sacrificial layer 21 and second sacrificial layer 22 were made of polyimide; however, they could also be made of polysilicon or aluminum. Removal of a sacrificial layer when using a polysilicon sacrificial layer is performed, for example, by wet etching that uses hydrazine or tetra-methyl ammonium hydroxide (TMAH), or dry etching that uses XeF₂ plasma. Removal of a sacrificial layer when using an aluminum sacrificial layer is performed by wet etching that uses chlorine or hot phosphoric acid. In this case, when Si nitride film is used for the insulating films in the diaphragm 1, first supporting sections 2 or second supporting sections 3, the Si nitride film could also be etched away if the hot phosphoric acid is too hot (˜160° C.), so care must be taken.

Moreover, when Si oxide film is used as the material of the diaphragm 1, first supporting sections 2 and second supporting sections 3, it is also possible to form the first sacrificial layer 21 and second sacrificial layer 22 using a Si nitride layer, and the opposite is also possible. Removal of a sacrificial layer in the case where the sacrificial layer is a Si nitride film, for example, is performed by wet etching using hot phosphoric acid. Removal of a sacrificial layer in the case where the sacrificial layer is a Si oxide film, for example, can be performed by wet etching using hydrofluoric acid.

In the embodiment above, a bolometer type thermal-type infrared solid-state imaging element comprising a thin bolometer film as the temperature change detection mechanism was described; however, the present invention is not limited to this. For example, the invention could similarly be applied to a thermal-type infrared solid-state imaging element that comprises a pn junction diode type detector as the temperature change detection mechanism.

### EXAMPLES

### Example 1

In order to check the effect of the present invention, a bolometer type thermal-type infrared solid-state imaging element having the construction illustrated in FIG. 1 was manufactured having 640×480 effective pixels with a pixel pitch of 17 μm, and 4 μm×4 μm square first supporting sections. The length of the beam 4 was 12.05+1.4+11.1+1.4+11.1+1.4+11.1+1.4+11.1+1.4+7.55=71 μm, the width was 0.9 μm and the thickness was 300 nm, and the width of the second wiring 14 in the beam 4 was 0.5 μm with a thickness of 50 nm. SiN was used for all of the insulating films of the diaphragm 10, first support sections 2 and second support sections 3. Vanadium oxide was used as the thin bolometer film 17. TiAlV was used as the conductive wiring material. The thermal conductivity of SiN is 0.0065 W/cmK, and the thermal conductivity of TiAlV is 0.11 W/cmK, so that the thermal conductance Gth is 2×(0.0065×0.9E-4×300E-7+0.11×0.5E-4×50E-7)/71E-4=1.27E-8 W/K.

On the other hand, for a comparison of performance, a bolometer type thermal-type infrared solid-state imaging element having 640×480 effective pixels with a pixel pitch of 23.5 μm, which was developed by the inventors and others prior to the invention and presented as a paper in “Optical Engineering, vol. 45(1), pp. 014001-1-014001-10, 2006”, was used. The mask dimension of the beam width is 1 μm; however, the completed dimension is somewhat narrower, so that the cross-sectional shape of the beam is the same as in this example and is easy to compare. The thermal conductance Gth of the structure of this bolometer type infrared solid-state imaging element is 3E-8 W/K. Therefore, the Gth ratio becomes 1.27E-8/3E-8=42.3%, and it could be confirmed that by using the construction of the supporting sections of the present invention it is possible to greatly reduce the thermal conductance.

Moreover, in the case of the construction of this example of the present invention, the surface area of the diaphragm is (16.5 μm×16.5 μm)−((4.5 μm×4.5 μm)×2)=231.75 μm². The surface are of the thin bolometer film 17 is 4.8 μm×(11.25 μm+15.5 μm+11.25 μm)=182.4 μm². On the other hand, in the case of the construction of the bolometer type thermal-type infrared solid-state imaging element described above, the surface area of the diaphragm, when taking into consideration an aperture ratio of 60% and shading effect of 1.28 times, corresponds to (23.5 μm×23.5 μm)×0.6×1.28=424.13 μm², and the surface area of the thin bolometer film is 5.5 μm×(12 μm+18 μm+12 μm)=231 μm². Therefore, the diaphragm area ratio is 231.75/424.13=54.6%, and the area ratio of the thin bolometer film is 182.4/231=79.0%.

Here, the diaphragm area and photo-response output are in a proportional relationship, and the thin bolometer film area and the 1/f noise are in an inversely proportional relationship. Furthermore, the Gth and photo-response output are in an inversely proportional relationship. Moreover, NETD=noise/photo-response output. Therefore, the NETD ratio=Gth/(diaphragm area ratio×thin bolometer film area ratio). Inserting numerical values into this equation results in NETD ratio=42.3%/(54.6%×79.0%)=0.981, and can be estimated to be a nearly equivalent (somewhat good) NETD. Actually, when evaluated using an F1 lens, an equivalent NETD: 50 mK could be obtained regardless of major miniaturization.

The dimensions of the thermal-type infrared solid-state imaging element chip of this example are 15 mm×15 mm, and this is arranged and formed on a 6-inch wafer. The wafer where the first supporting sections are provided according to the invention, and the wafer where a mechanical and electrical connection is formed between the diaphragm and first contact sections of the second supporting sections without providing first supporting sections (equivalent to the construction disclosed in patent literature 1 and 2) were manufactured separately in the same lot, and difference in the defective rate in abnormal sensitivity distribution of the chip was confirmed. In the latter wafer in which first supporting sections were not provided, the chips on the outermost perimeter of the wafer exceeded that allowable range and were found to be defective. Of 52 chips on the wafer surface, 20 chips on the outermost perimeter of the wafer were defective, so that the defective rate was 38.5%. On the other hand, in the case of the wafer of the present invention, there were no defective chips among the chips on the outermost perimeter of the wafer, and because there were 0 defective chips, it could be confirmed that there was an improvement in yield by the amount of the defective rate above.

An evaluation camera in which a thermal-type infrared solid-state imaging element chip of this example was used was placed in an automobile, and the fluctuation in sensitivity of an image as the automobile was operated was evaluated. As a result, the fluctuation in sensitivity of the image was at the detectable limit or less, and a good image with no shakiness could be obtained, and thus the effectiveness of this construction could be confirmed.

### Example 2

A bolometer type thermal-type infrared solid-state imaging element having the construction illustrated in FIG. 3 was manufactured having a pixel pitch of 17 μm, and 2.5 μm×2.5 μm square first contact sections 2. The length of the beam 4 was 13.5+1.5+12.5+1.5+15.5+1.5+15.5+1.5+12=75 μm, the width was 1 μm and the thickness was 300 nm, and the width of the second wiring 14 in the beam 4 was 0.5 m with a thickness of 50 nm. SiN was used for all of the insulating films of the diaphragm 1, first support sections 2 and second support sections 3. Vanadium oxide was used as the thin bolometer film 17. TiAlV was used as the conductive wiring material.

The thermal conductivity of SiN is 0.0065 W/cmK, and the thermal conductivity of TiAlV is 0.11 W/cmK, so that the thermal conductance Gth is 2×(0.0065×1E-4×300E-7+0.11×0.5E-4×50E-7)/75E-4=1.25E-8 W/K. Therefore, it could be confirmed that the performance of the construction of FIG. 3 was the same as that of the first example.

An embodiment and examples of the present invention were explained above, however, the present invention is not limited to the embodiment and examples described above, and various embodiments are possible within the scope of the present invention.

The following construction is included as a preferred variation of the present invention.

A feature of the thermal-type infrared solid-state imaging element of the present invention, and more preferably, the beam of the second supporting section is construction in which the beam is folded back at the bending points.

Furthermore, preferably the pixels are arranged in an array with a pitch being equal to the diaphragm length and the gap between diaphragm having a length about the same as the connections section.

Furthermore, preferably the pair of supporting sections have n layers (integer n≧1) of other supporting sections between the supporting sections and the substrate, wherein

the other supporting section is mechanically and electrically connected between the second contact section of the second supporting section and the first contact section of the other supporting section one layer below; and

when n is 2 or greater, the other supporting sections are mechanically and electrically connected in order between the second contact section of another supporting section of a certain layer and the first contact section of another supporting section one layer below;

with the second contact section of the other supporting section of the very bottom layer being mechanically and electrically connected with the connecting electrode.

Preferably, the beams and second contact sections of the pair of supporting sections are arranged point symmetrically on both sides of the diaphragm with the diaphragm in the center.

Preferably, the connecting sections are areas that are made narrower than the width of the first supporting sections by slits that are formed between the first supporting sections and the diaphragm.

Preferably, a metal film that is different than that of the wiring located on the beam is formed in the bottom sections of the first contact sections and second contact sections.

This application claims priority based upon Unexamined Japanese Patent Application KOKAI Publication No. 2008-273564, filed on Oct. 23, 2008, the entire disclosure of the aforesaid application being incorporated herein by reference.

### Industrial Applicability

As an example of the application of the present invention is a thermal-type infrared solid-state imaging element that is used in a night-vision device (infrared camera), or in thermography.

### EXPLANATION OF REFERENCE NUMERALS

1: Diaphragm
2: First supporting section
3: Second supporting section
4: Beam
5: First contact section
6: Second contact section
7: Slit
8: Bending point
9: Connecting section
10: Si substrate
11: Connecting electrode
12: First insulating film
13: First wiring
14: Second wiring
15: Second insulating film
16: Third insulating film
17: Thin bolometer film
18: Fourth insulating film
19: Third wiring
20: Fifth insulating film
21: First sacrificial layer

1-7. (canceled)

8. A thermal-type infrared solid-state imaging element comprising a plurality of pixels having at least:
a substrate on which an integrated circuit is formed for reading signals, and that comprises that integrated circuit and a connecting electrode;
a diaphragm having an infrared absorption section that is heated by absorbing infrared rays, a temperature detection section whose temperature changes by the heat from the infrared absorption section and detects changes in the temperature of the infrared absorption section, and an electrode section that is electrically connected to the temperature detection section; this diaphragm being located in a space provided on the surface of one side of the substrate; and
a pair of supporting sections that support the diaphragm such that the diaphragm is separated from the surface on one side of the substrate, and of which at least part is formed of an electrically conductive material, so as to form wiring that electrically connects the electrode section of the diaphragm with the connecting electrode of the substrate; wherein
the pair of supporting sections each has a first supporting section that is provided on the same level as the diaphragm, part thereof connecting to the diaphragm by a connecting section, and a second supporting sections that is provided on a level between the diaphragm and the substrate;
the connecting section is an area provided between the first supporting section and the diaphragm having a width that is less than the first supporting section;
the second supporting section has a beam that has one or more bending points, a first contact section that is provided on one end of the beam, and a second contact section that is provided on the other end of the beam;
the beam and second contact section of each of the pair of supporting sections are located on both sides on the outside of the diaphragm with the diaphragm in between;
each of the pair of supporting sections forms a mechanical and electrical connection between the first supporting section and the first contact section of the second supporting section, and forms a mechanical and electrical connection between the second contact section of the second supporting section and the connecting electrode; and
the beam and second contact section of the second supporting section of each pixel are located underneath the diaphragm of another pixel.

9. The thermal-type infrared solid-state imaging element according to claim 8, wherein the beam of the second supporting section has folded construction at the bending points.

10. The thermal-type infrared solid-state imaging element according to claim 8, wherein
the pixels are arranged in an array shape having a pitch that is equal the diaphragm length and the gap between diaphragms that is about the same length as the connecting section.

11. The thermal-type infrared solid-state imaging element according to claim 8, wherein
the pair of supporting sections further have other supporting sections on n levels (integer n≧1) between the second supporting sections and the substrate;
the other supporting section forms a mechanical and electrical connection between the second contact section of the second supporting section and the first contact section of the other supporting section of one level below;
when n is two or greater, the other supporting sections sequentially form mechanical and electrical connections between the second contact section of the other supporting section of a specified level and the first contact section of the other supporting section one level below; and
a mechanical and electrical connection is formed between the second contact section of the other supporting section of the very bottom level and the connecting electrode.

12. The thermal-type infrared solid-state imaging element according to claim 8, wherein the beams and second contact sections of each of the pair of supporting sections are point symmetrically arranged on both sides of the diaphragm with the diaphragm in the center.

13. The thermal-type infrared solid-state imaging element according to claim 8, wherein the connecting section is an area that is made narrow by a slit that provided between the first supporting section and the diaphragm.

14. The thermal-type infrared solid-state imaging element according to claim 8, wherein a metal film separate from the wiring located on the beam is formed in the bottom section of the first contact section and second contact section.
